(19) United States
(12) Patent Application Publication
(10) Pub. No.: US 2002/0179936 A1
(43) Pub. Date: Dec. 5, 2002

(54) Structure and method for fabricating semiconductor structures and devices which include quaternary chalcogenides

(75) Inventor: Ravindranath Droopad, Chandler, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL

(21) Appl. No.: 09/870,828

(22) Filed: Jun. 1, 2001

(51) Int. Cl. H01L 31/0328; H01L 31/0336; H01L 31/072; H01L 31/109

(52) U.S. Cl. 257/200

(57) ABSTRACT

High quality epitaxial layers of monocrystalline materials can be grown overlying monocrystalline substrates such as large silicon wafers by forming a compliant substrate for growing the monocrystalline layers. The compliant substrate is utilized in fabrication methods and devices for growing quaternary chalcogenides on silicon

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include quaternary chalcogenides.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

High quality monocrystalline materials are used in the formation of UV detectors and short wavelength lasers. Currently, the ZnMgBeSe-quaternary alloy is being grown on GaAs substrates to form such devices. Growth of ZnMgBeSe on a high quality monocrystalline thin film as opposed to a bulk wafer of semiconductor material such as GaAs would significantly reduce the cost of making such devices.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film the same crystal orientation as an underlying substrate. This monocrystalline material layer may be comprised of a semiconductor material, a compound semiconductor material, and other types of material such as metals and non-metals. In forming tunable UV detectors and short wavelength lasers, the high quality monocrystalline material layer is a ZnMgBeSe quaternary chalcogenide.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9A-9D illustrate schematically, in cross-section, the formation of a device structure in accordance with another embodiment of the invention;

FIGS. 10A-10D illustrate a probable molecular bonding structure of the device structures illustrated in FIGS. 9A-9D;

FIGS. 11-13 illustrate schematically, in cross-section, the formation of a device structure in accordance with still another embodiment of the invention;

FIG. 14 illustrates schematically, in cross-section, a semiconductor structure fabricated in accordance with yet another embodiment of the present invention;

FIG. 15 illustrates schematically, in cross-section, a semiconductor structure fabricated in accordance with still another embodiment of the present invention;

FIG. 16 illustrates schematically, in cross-section, a semiconductor structure formed in accordance with the present invention which includes a wave guide coupled to a detector;

FIG. 17 illustrates schematically, in cross-section, a semiconductor structure formed in accordance with the present invention which includes a wave guide coupled to a multiple quantum well; and

FIG. 18 illustrates schematically, in cross-section, a semiconductor structure formed in accordance with the present invention which includes a detector.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

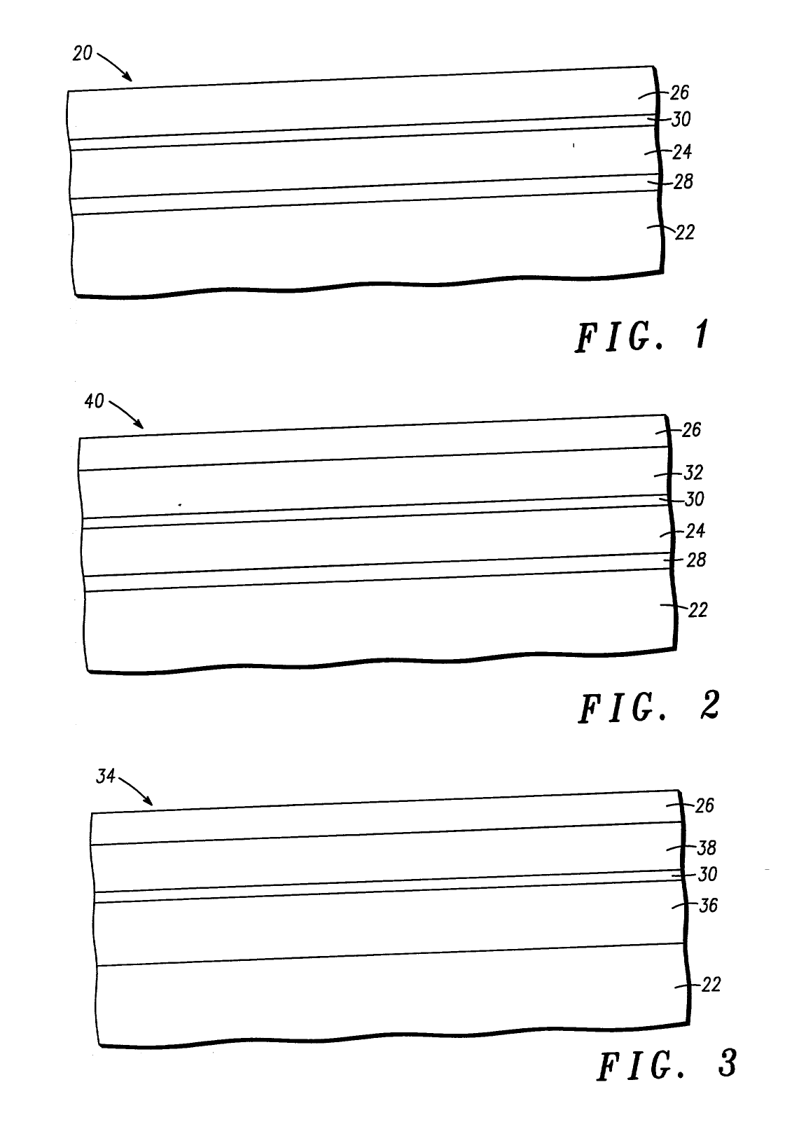

FIG. 1 illustrates schematically, in cross section, a portion of a semiconductor structure 20 in accordance with an embodiment of the invention. Semiconductor structure 20 includes a monocrystalline substrate 22, an accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits such as, for example, the use of ZnMgBeSe in fabricating UV detectors and short wavelength lasers.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the compound semiconductor layer from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (BaO—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

In still another embodiment of the invention, a quaternary chalcogenide ZnMgBeSe semiconductor is grown on a silicon substrate using epitaxial oxide buffer layers. The substrate is preferably a silicon wafer and a suitable accommodating buffer layer material is SrₓBa₁₋ₓTiO₃, where x ranges from 0-1, having a thickness of about 2-100 nm and preferably a thickness of about 5-15 nm. Monocrystalline material layer 26 comprises the quaternary alloy ZnMgBeSe and template layer 30 is the compound semiconductor material ZnSe.

### EXAMPLE 5

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 6

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The buffer layer preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 7

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

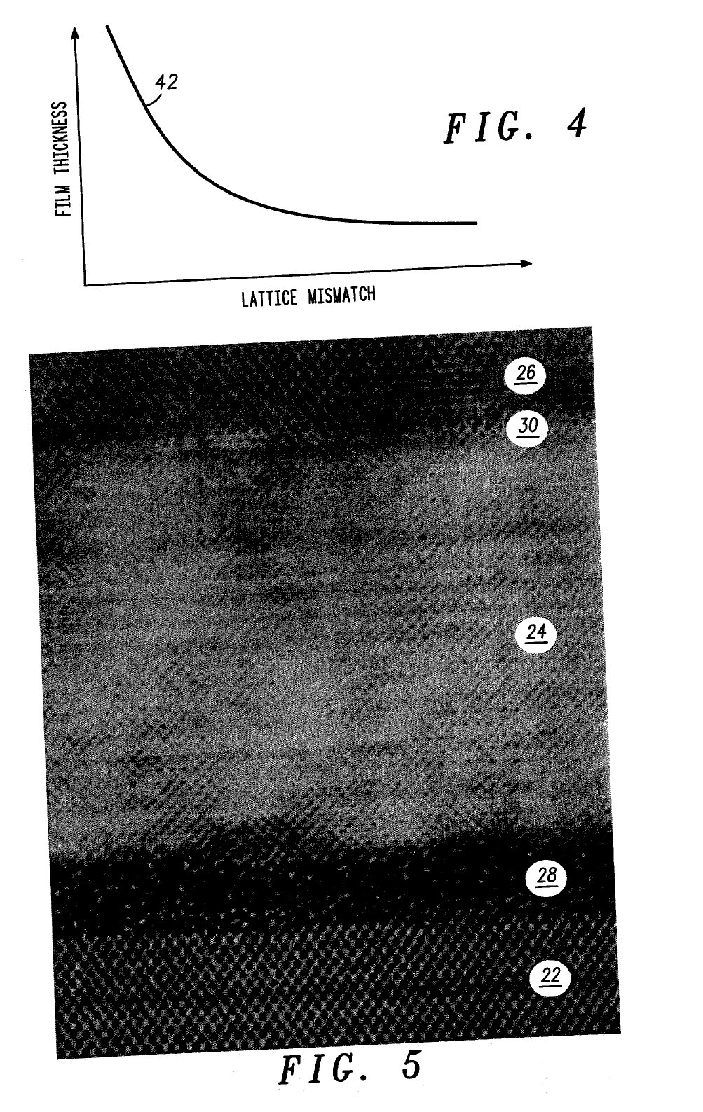

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stochiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered monocrystal with the crystalline orientation rotated by 45° with respect to the ordered 2×1 crystalline structure of the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

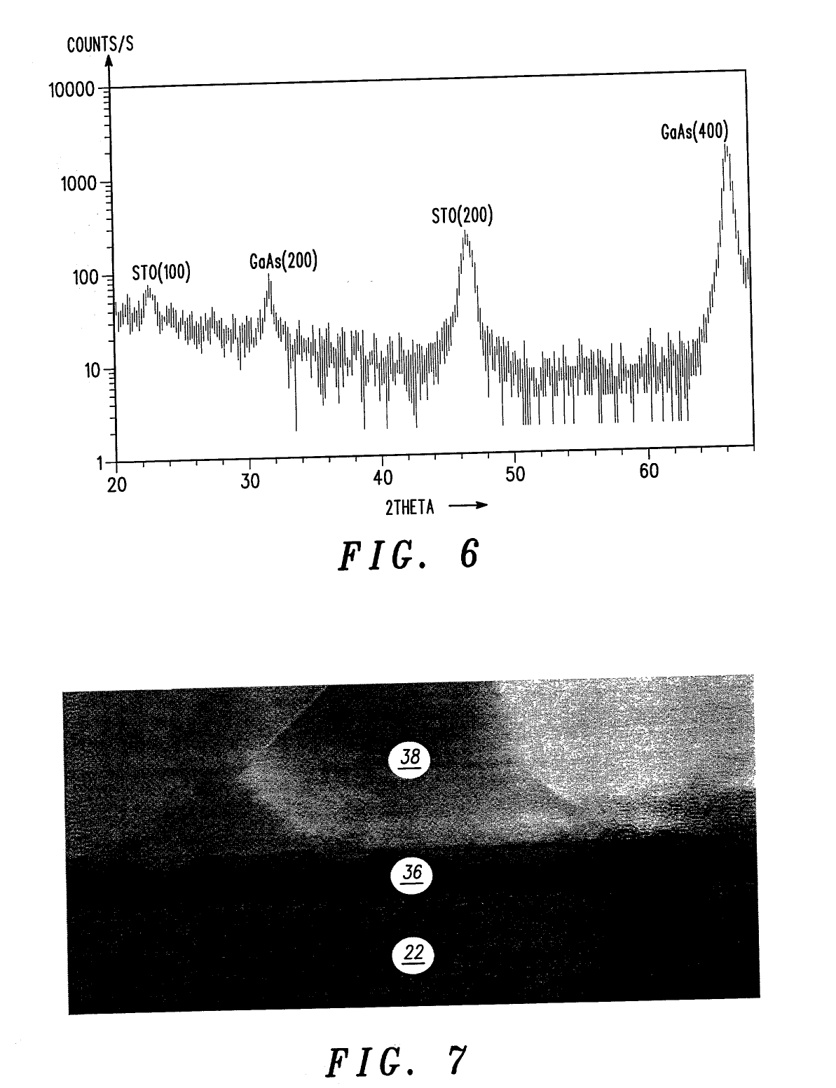

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) oriented.

The structure illustrated in FIG. 2 can be formed by the process discussed above with the addition of an additional buffer layer deposition step. The buffer layer is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In Accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

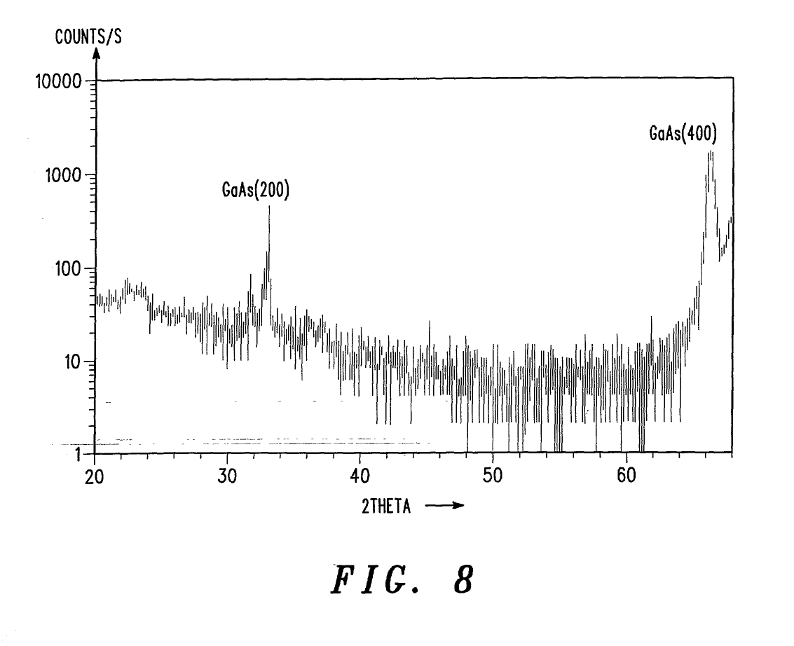

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, peroskite oxides such as alkaline earth metal tin-based perovskites, lanthanum aluminate, lanthanum scandium oxide, and gadolinium oxide can also be grown. Further, by a similar process suchas MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

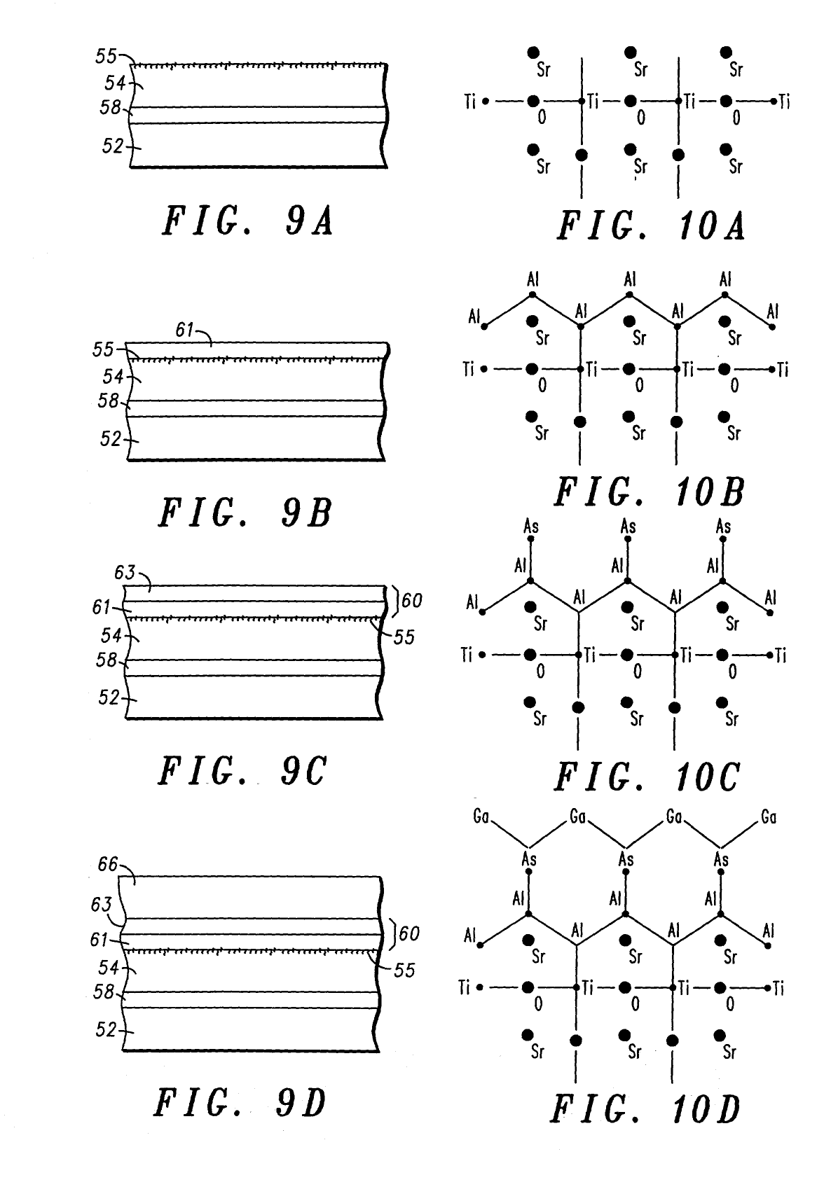

The formation of a device structure in accordance with another embodiment of the invention is illustrated schematically in cross-section in FIGS. 9A-9D. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9A-9D utilizes a template that includes a surfactant to facilitate layer-by-layer monocrystalline material growth.

Turning now to FIG. 9A, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference to layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9A by hatched line 55 which is followed by the addition of a template layer 60 which includes a surfactant layer 61 and capping layer 63 as illustrated in FIGS. 9B and 9C. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 9B by way of MBE, although other epitaxial processes may also be performed including CVD, MOCVD, MEE, ALE, PVD, CSD, PLD, or the like.

Surfactant layer 61 is then exposed to a gas such as arsenic, for example, to form capping layer 63 as illustrated in FIG. 9C. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 9D.

FIGS. 10A-10D illustrate possible molecular bond structures for a specific example of a compound semiconductor structure formed in accordance with the embodiment of the invention illustrated in FIGS. 9A-9D. More specifically, FIGS. 10A-10D illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 100 nm where the two-dimensional (2D) and three-dimensional (3D) growth shifts because of the surface energies involved. In order to maintain a true layer by layer growth (Frank Van der Merle growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation in the absence of surface modification, a surfactant containing template was used, as described above with reference to FIGS. 9B-9D, to increase the surface energy of the monocrystalline oxide layer 54 and also to shift the crystalline structure of the template to a diamond-like structure that is in compliance with the original GaAs layer.

FIG. 10A illustrates the molecular bond structure of a strontium terminated surface of a strontium titanate monocrystalline oxide layer. An aluminum surfactant layer is deposited on top of the strontium terminated surface and bonds with that surface as illustrated in FIG. 10B, which reacts to form a capping layer comprising a monolayer of Al₂Sr having the molecular bond structure illustrated in FIG. 10B which forms a diamond-like structure with an sp³ hybrid terminated surface that is compliant with compound semiconductors such as GaAs. The structure is then exposed to As to form a layer of AlAs as shown in FIG. 10C. GaAs is then deposited to complete the molecular bond structure illustrated in FIG. 10D which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 24 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, asurfactant containing template may be used for the monolithic integration of a monocrystalline material layer such as a layer comprising germanium, for example, to form high efficiency photocells.

FIGS. 11-13 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 11 includes a monocrystalline substrate 102, an amorphous interface layer 108 and an accommodating buffer layer 104. Amorphous intermediate layer 108 is grown on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2 but preferably comprises a silicon oxide. Substrate 102 is preferably silicon but may also comprise any of those materials previously described with reference to substrate 22 in FIGS. 1-3, and accompanying buffer layer is preferably a strontium barium titanate layer, but may include any of the materials described above in connection with layer 24 in FIGS. 1-2.

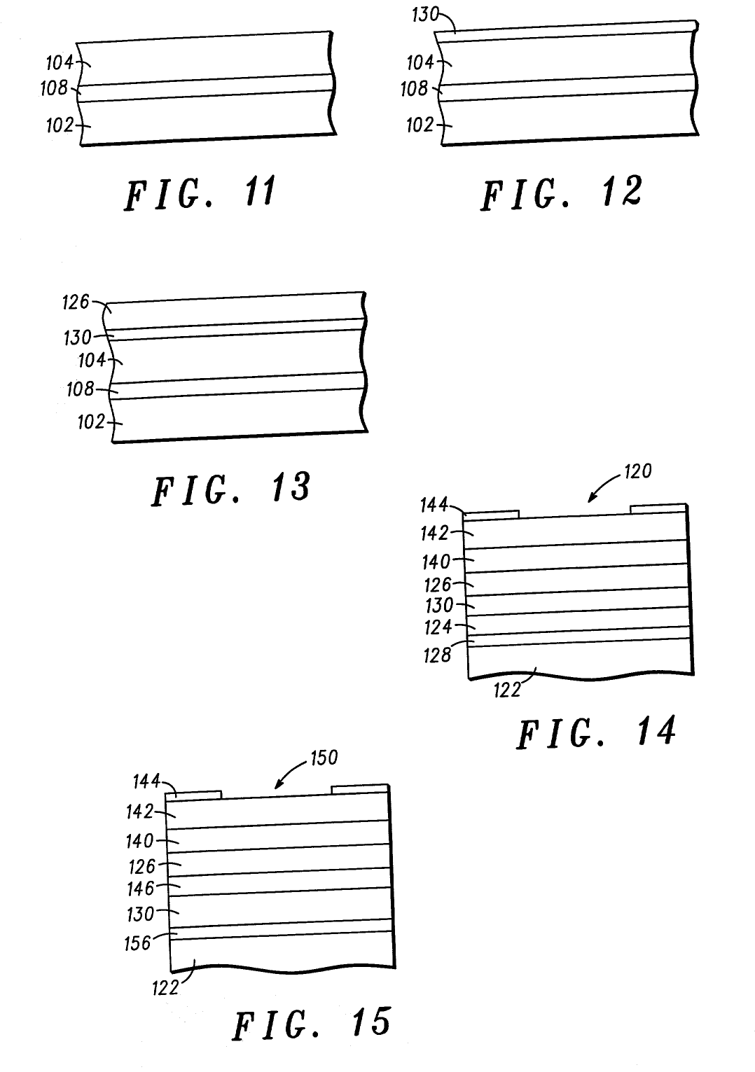

A template layer 130 is deposited over accommodating buffer layer 104 as illustrated in FIG. 12 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂.

A monocrystalline material layer 126 is epitaxially grown over template layer 130 to achieve the final structure illustrated in FIG. 13. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Embodiments shown in FIGS. 14-18 of the present invention are directed to the growth of ZnMgBeSe on silicon using epitaxial oxide buffer layers. The Group II-III semiconductor ZnSe has a band gap of 2.7 eV and is closely lattice matched to GaAs. Some UV radiation can be detected with this band gap. The present invention adds Mg and Be to ZnSe to enable the quaternary alloy ZnMgBeSe to grow lattice matched to GaAs.

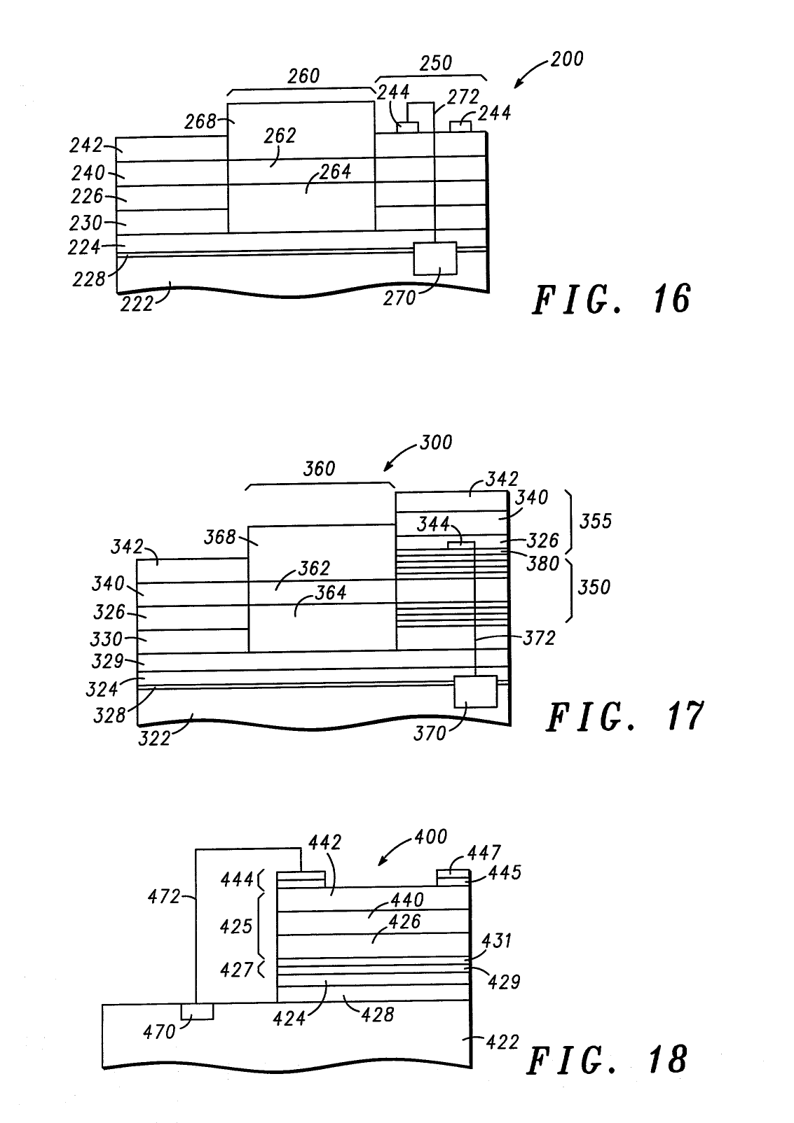

FIGS. 14-15 illustrate cross-sections of semiconductor structures in accordance with still other exemplary embodiments of the present invention. The structures are formed by depositing the quaternary alloy ZnMgBeSe on an oxide layer grown epitaxially on a silicon substrate. More specifically, the formation of structure 120 begins with an amorphous intermediate layer 128 such as amorphous silicon oxide positioned between a substrate 122 and an epitaxially grown oxide layer 124. Amorphous intermediate layer 128 is grown on substrate 122 at the interface between substrate 122 and growing oxide layer 124 by the oxidation of substrate 122 during the growth of layer 124.

Structure 120 also includes a template layer 130 between oxide layer 124 and a first impurity doped monocrystalline ZnBeSe layer 126, and an intrinsic region comprising a second undoped monocrystalline ZnBeSe layer 140 positioned between first impurity doped ZnBeSe layer 126 and a third impurity doped ZnBeSe layer or impurity doped ZnMgBeSe layer 142. A contact layer 144 may be deposited over impurity-doped ZnMgBeSe layer 142. Third impurity-doped ZnMgBeSe layer 142 has a larger band gap than second undoped ZnBeSe layer 140 and thereby functions to reduce losses due to surface recombination.

FIG. 15 illustrates a structure 150 similar to structure 120 in FIG. 14 with the exception of a monocrystalline buffer layer 146 positioned between template layer 130 and first impurity-doped ZnBeSe layer 126. FIG. 15 also includes amorphous epitaxial oxide layer 156 which is formed by an anneal process which converts layer 124 and layer 128 to an amorphous layer as previously described in reference to FIG. 3. Substrate 122 is preferably a monocrystalline silicon wafer and oxide layer 124 is preferably a monocrystalline oxide material selected for its crystalline compatibility with the underlying substrate and the overlying material. Oxide layer 124 is preferably comprised of a monocrystalline layer of Sr_{z}Ba_{1-z}TiO₃ where z ranges from 0 to 1. However, layer 124 may also comprise any of those compounds previously described with reference to layer 24 in FIGS. 1 and 2, layer 59 in FIG. 9D, and layer 104 in FIG. 13, and any of those compounds previously described with reference to layer 36 in FIG. 3 which is formed from layers 24 and 28 referenced in FIGS. 1 and 2.

Template layer 130 preferably comprises 1-10 monolayers including elements selected from the group consisting of zinc and oxygen, strontium and oxygen, barium and oxygen, titanium and arsenic, strontium, oxygen and arsenic, and strontium, gallium and oxygen. However, template layer 130 may also include any of the materials previously identified with reference to layer 30 in FIGS. 1-3, layer 60 in FIG. 9D, and layer 130 in FIG. 13.

In forming structures 120 and 150, template layer 130 is deposited by way of MBE, CVD, MOCVD, MEE, ALE, PVD, CSO, PLD, or the like. First impurity-doped ZnBeSe layer 126 may comprise an n-type dopant and third impurity-doped ZnMgBeSe layer 142 may comprise a p-type dopant thereby forming a p-i-n structure. Optional buffer layer 146 shown in FIG. 15 which is grown over template layer 130 may comprise GaAs or ZnSe.

The Be-containing chalcogenides such as ZnMgBeSe are know to resist the formation and propagation of defects due to strong covalent bonding present in the crystal lattice. By varying the Be and Mg content in quaternary layers 126, 140 and 142, the direct band gap can be tuned in the range of 2.7 eV to more than 3.5 eV.

Quaternary layers 126, 140 and 142 have a band gap that is direct and therefore suitable for laser fabrication. Quantum wells can be formed from the larger band gap ZnMgBeSe without changing the lattice constant of the structure. The lattice parameter is the same for all values of Be and Mg. This type of quantum well structure can act as the active region of a laser structure with oxide layers acting as cladding layers.

Turning now to FIG. 16, a semiconductor structure 200 formed in accordance with the present invention which includes a wave guide coupled to a detector is shown in cross-section. A monocrystalline oxide layer 224 is epitaxially grown over a monocrystalline semiconductor substrate layer 222, such as silicon. An amorphous oxide layer 228 is formed underlying layer 224 during the epitaxial growth of oxide layer 224. A template layer 230 is then formed over oxide layer 224 which is followed by growing a series of monocrystalline ZnBeSe layers. More specifically, a first impurity-doped ZnBeSe layer 226 is epitaxially grown over template layer 230, a second undoped ZnBeSe layer 240 is epitaxially grown over first impurity-doped ZeBeSe layer 226, and a third impurity-doped ZnBeSe or ZnMgBeSe layer 242 is epitaxially grown over second undoped ZnBeSe layer 240.

Impurity-doped ZnBeSe layers 226 and 242 may be oppositely doped with n-type or p-type dopants to form various devices. For example, with reference to FIG. 16, impurity-doped layer 226 may comprise an n-type dopant and impurity-doped layer 242 may comprise a p-type dopant to form a p-i-n diode 250. With further reference to FIG. 16, an alkali earth metal titanate material is deposited and patterned to form a wave guide 260 in alignment with and coupled to p-i-n diode 250. Wave guide 260 includes a core 262 that is surrounded by a bottom cladding layer 264 and a top cladding layer 268. Core 262 preferably comprises (Ba, Sr)TiO₃ and is aligned with and coupled to second undoped layer 240 of p-i-n diode 250. Cladding layers 264 and 268 preferably comprise barrium strontium titanate where the composition is selected such that the refractive index is less than the core. A circuit 270 is formed at least partially in substrate 222 and coupled to the p-i-n diode 250 via conducting line 272 and contact 244.

Circuit 270 may include any device suitable for driving p-i-n diode 250 and may be formed within any suitable semiconductor material. For example, the semiconductor material may include Group IV compounds such as silicon, germanium, silicon germanium, silicon germanium carbide, or compound semiconductor material such as GaAs and other materials discussed above in connection with Examples 1-7 provided above.

Although not illustrated, structure 200 may include other electronic circuits in addition to circuit 270. For example, structure 200 may include tuning circuits, feedback control circuits, and the like.

In accordance with the present invention, a cross-section of a semiconductor structure 300 having a wave guide coupled to a multiple quantum well is shown in FIG. 17. A monocrystalline oxide layer 324 is epitaxially grown over a monocrystalline semiconductor substrate 322, such as Si, to form an amorphous oxide layer 328. A buffer layer 329 is grown over oxide layer 324 followed by a template layer 330. The buffer layer 329 preferably comprises a GaAs material or ZnSe material that is epitaxially grown over oxide layer 324. Oxide layer 324 preferably comprises (Ba, Sr)TiO₃. Template layer 330 is formed over buffer layer 329 by depositing 1-10 monolayers of materials including zinc and oxygen, strontium and oxygen, titanium and arsenic, strontium, oxygen and arsenic, and strontium, gallium and oxygen.

A series of epitaxially grown monocrystalline ZnBeSe layers are then grown over buffer layer 329 to form quantum well regions. More specifically, a ZnMgBeSe monocrystalline layer 326 is epitaxially grown over template layer 330 and a monocrystalline ZnBeSe layer 340 is epitaxially grown over layer 326. Another ZnMgBeSe layer 342 is grown over layer 340 to form a quantum well. Multiple quantum wells, such as quantum well 355, are formed by repeating the series of layers 326, 340 and 342, in that order, to form a stack of quantum wells. Layer 340 may be referred to as the well region of quantum well 355, while layers 326 and 342 may be referred to as first and second barrier layers of quantum well 355. The band gap of any barrier layer overlying a well region should be greater than the band gap of the well region.

First barrier layer 326, quantum well region 340, and second barrier layer 342 are patterned to form laser structure 350. A cladding layer 380 may also be deposited over laser structure 350. Cladding layer 380 may comprise any of those materials previously described with reference to oxide layers 24, 54, 104, 120, 224 and 324 in FIGS. 1, 2, 9A-D, 11-13, 14, 16 and 17, respectively.

An alkali earth metal titanate layer is deposited and patterned to form an optical wave guide 360 next to laser structure 350, wave guide 360 having a core 362 surrounded by a bottom cladding layer 364 and a top cladding layer 368. Optical wave guide 360 is aligned with and optically coupled to laser structure 350.

Growth of any epitaxially grown layers may be performed by MSE, MOCVD, MEE, CVD, PVD, PLD, CSD and ALE. Suitable photolithographic and etching techniques well known in the art are used where patterning occurs to form additional structures.

An integrated circuit 370 is formed at least partially in substrate 322 and coupled to contact 344 by way of conducting line 372. Circuit 370 may include any device for driving laser 350 and structure 300 may also include other electronic circuits such as those previously described with reference to FIG. 16. Core 362 and cladding layers 364 and 368 preferably comprise oxide layers and more preferably comprise (Ba, Sr)TiO₃.

Another embodiment of the present invention includes a UV detector such as that shown in FIG. 18. Important applications for UV detectors include in-situ monitoring of combustion, UV dosimetry for personal exposure levels, and UV astronomy. UV light detection is currently performed by using conventional semiconductors such as Si or GaAs with filters.

A cross-sectional view of a UV detector structure 400 formed in accordance with the present invention is shown in FIG. 18. UV detector 400 includes an amorphous strain relief layer 428, preferably comprising silicon oxide, deposited over a monocrystalline semiconductor substrate 422. An oxide layer 424 is epitaxially grown over strain relief layer 428, and a monocrystalline ZnBeSe p-en diode 425 is formed overlying oxide layer 424. A monocrystalline buffer layer 427 may be formed between oxide layer 424 and p-i-n diode 452 and preferably comprises a first GaAs layer 429 and a second ZnSe layer 431. Buffer layer 427 may also comprise only ZnSe or only GaAs.

A contact layer 444 is deposited over p-i-n diode 425. Contact layer 444 may comprise any suitable conductive material but preferably comprises a first layer of ZnSe 445 and a second layer of BeTe 447. UV detector 400 further includes a control circuit 470 coupled to contact layer 444 via conducting line 472 to drive UV detector 400. As previously stated with reference to FIGS. 16 and 17, circuit 470 may also comprise other types of circuits which aid the function of the device.

As previously described with reference to FIGS. 14-16, the ZnBeSe p-i-n diode comprises a first ZnBeSe layer 426 doped with an n-type dopant which underlies a second undoped ZnBeSe layer 440 which underlies a third ZnBeSe layer 442 doped with a p-type dopant.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g., conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A compound semiconductor device structure comprising:
a monocrystalline semiconductor substrate;
an oxide layer epitaxially grown overlying the substrate;
a template layer formed overlying the oxide layer;
a first layer of impurity doped monocrystalline ZnBeSe overlying the template layer;
a second layer of undoped monocrystalline ZnBeSe overlying the first layer; and
a third impurity doped layer comprising a material selected from the group consisting of ZnBeSe and ZnMgBeSe overlying the second layer.

2. The device structure of claim 1 wherein the oxide layer comprises an alkali earth metal titanate.

3. The device structure of claim 1 wherein the oxide layer comprises (Ba,Sr)TiO₃.

4. The device structure of claim 1 wherein the oxide layer comprises a monocrystalline oxide layer.

5. The device structure of claim 1 wherein the oxide layer comprises an amorphous oxide layer.

6. The device structure of claim 1 wherein the substrate comprises silicon.

7. The device structure of claim 6 further comprising an amorphous silicon oxide layer underlying the oxide layer.

8. The device structure of claim 6 further comprising an integrated circuit formed at least partially in the substrate.

9. The device structure of claim 1 further comprising a monocrystalline buffer layer underlying the first layer.

10. The device structure of claim 9 wherein the monocrystalline buffer layer comprises a material selected from the group consisting of GaAs and ZnSe.

11. The device structure of claim 10 wherein the oxide layer comprises (Ba,Sr)TiO₃.

12. The device structure of claim 11 wherein the template layer comprises 1-10 monolayers comprising elements selected from the group consisting of zinc and oxygen, strontium and oxygen, barium and oxygen, titanium and arsenic, strontium, oxygen and arsenic, and strontium, gallium and oxygen.

13. The device structure of claim 1 wherein the first layer is doped n-type and the third layer is doped p-type.

14. The device structure of claim 1 wherein the third layer has a wider band gap than the second layer.

15. The device structure of claim 1 wherein the first layer, second layer, and third impurity doped layer collectively form, in part, a UV detector.

16. The device structure of claim 15 further comprising a control circuit formed at least partially in the substrate and coupled to the UV detector.

17. The device structure of claim 15 further comprising a wave guide aligned with and coupled to the UV detector.

18. The device structure of claim 17 wherein the wave guide comprises a layer of (Ba,Sr)TiO₃ aligned with the second layer.

19. A compound semiconductor device structure comprising:
a monocrystalline semiconductor substrate;
an accommodating oxide buffer layer epitaxially grown overlying the substrate; and
a monocrystalline compound semiconductor quantum well structure capable of emitting UV radiation formed overlying the accommodating oxide buffer layer.

20. The device structure of claim 19 wherein the quantum well structure comprises:
a first layer of monocrystalline ZnBeMgSe;
a second layer of monocrystalline ZnBeSe overlying the first layer; and
a third layer of monocrystalline ZnBeMgSe formed overlying the second layer.

21. The device structure of claim 20 further comprising a ZnSe buffer layer formed underlying the first layer.

22. The device structure of claim 19 wherein the quantum well structure comprises a multiple quantum well structure comprising a plurality of layers of ZnBeSe each sandwiched between layers of ZnBeMgSe.

23. The device structure of claim 22 further comprising a ZnSe buffer layer formed underlying the multiple quantum well structure.

24. The device structure of claim 19 further comprising cladding layers positioned above and below the quantum well structure.

25. The device structure of claim 24 wherein the cladding layers comprise oxide layers.

26. The device structure of claim 25 wherein the oxide layers comprise (Ba,Sr)TiO₃.

27. The device structure of claim 19 wherein the accommodating oxide buffer layer comprises (Ba,Sr)TiO₃.

28. The device structure of claim 19 further comprising a control circuit formed at least partially in the substrate and configured to control the output of UV radiation from the quantum well structure.

29. The device structure of claim 19 further comprising a wave guide aligned with and coupled to the quantum well structure to receive UV radiation emitted from the quantum well structure.

30. The device structure of claim 19 further comprising a GaAs buffer layer formed underlying the quantum well structure.

31. The device structure of claim 19 further comprising a first GaAs buffer layer and a second ZnSe buffer layer formed underlying the quantum well structure.

32. A UV detector structure comprising:
a monocrystalline semiconductor substrate having a surface;
an amorphous strain relief layer formed at the substrate surface;
an oxide layer formed overlying the strain relief layer; and
a monocrystalline ZnBeSe p-i-n diode formed overlying the oxide layer.

33. The structure of claim 32 wherein the substrate comprises silicon.

34. The structure of claim 33 wherein the strain relief layer comprises silicon oxide.

35. The structure of claim 34 further comprising a detector control circuit formed at least partially in the substrate and coupled to the p-i-n diode.

36. The structure of claim 34 wherein the oxide layer comprises (Ba,Sr)TiO₃.

37. The structure of claim 36 wherein the oxide layer comprises a monocrystalline oxide layer.

38. The structure of claim 36 wherein the oxide layer comprises an amorphous oxide layer.

39. The structure of claim 32 further comprising a monocrystalline buffer layer formed between the oxide layer and the monocrystalline ZnBeSe p-i-n diode.

40. The structure of claim 39 wherein the buffer layer comprises GaAs.

41. The structure of claim 39 wherein the buffer layer comprises a first layer of GaAs and a second layer of ZnSe overlying the first layer.

42. The structure of claim 39 wherein the buffer layer comprises ZnSe.

43. The structure of claim 32 further comprising a contact layer overlying the monocrystalline ZnBeSe p-i-n diode.

44. The structure of claim 43 wherein the contact layer comprises a first layer of ZnSe and a second layer of BeTe.

45. A process for fabricating a compound semiconductor structure comprising the steps of:
providing a monocrystalline semiconductor substrate;
epitaxially growing a monocrystalline oxide layer overlying the substrate;
forming an amorphous oxide layer underlying the monocrystalline oxide layer during the step of epitaxially growing a monocrystalline oxide layer;
forming a template layer overlying the monocrystalline oxide layer;
epitaxially growing a first monocrystalline layer comprising impurity doped ZnBeSe overlying the template layer;
epitaxially growing a second monocrystalline layer comprising undoped ZnBeSe overlying the first monocrystalline layer; and
epitaxially growing a third monocrystalline layer comprising an impurty doped compound semiconductor material overlying the second monocrystalline layer.

46. The process of claim 45 wherein the step of providing a monocrystalline semiconductor substrate comprises providing a substrate comprising silicon.

47. The process of claim 46 wherein the step of epitaxially growing a monocrystalline oxide layer comprises the step of growing an alkali earth metal titanate layer.

48. The process of claim 46 wherein the step of epitaxially growing a monocrystalline oxide layer comprises the step of growing a (Ba,Sr)TiO₃ layer.

49. The process of claim 48 wherein the step of forming an amorphous oxide layer comprises the step of increasing the partial pressure of oxygen above that necessary to grow (Ba,Sr)TiO₃ during the step of growing a (Ba,Sr)TiO₃ layer.

50. The process of claim 45 wherein the step of epitaxially growing a monocrystalline oxide layer comprises the step of growing a (Ba,Sr)TiO₃ layer.

51. The process of claim 50 wherein the step of forming a template layer comprises the step of depositing 1-10 monolayers comprising elements selected from the group consisting of zinc and oxygen, strontium and oxygen, and barium and oxygen.

52. The process of claim 50 further comprising the step of forming a monocrystalline buffer layer comprising a material selected from GaAs and ZnSe underlying the first monocrystalline layer.

53. The process of claim 48 wherein the step of forming a template layer comprises the step of depositing 1-10 monolayers comprising elements selected from the group consisting of zinc and oxygen, strontium and oxygen, barium and oxygen, titanium and arsenic, strontium, oxygen and arsenic, and strontium, gallium and oxygen.

54. The process of claim 45 wherein the step of epitaxially growing a third monocrystalline layer comprises the step of epitaxially growing a monocrystalline layer comprising a material selected from the group consisting of ZnBeSe and ZnBeMgSe.

55. The process of claim 54 wherein the step of epitaxially growing a first monocrystalline layer comprises epitaxially growing a layer doped with one doping type and the step of epitaxially growing a third monocrystalline layer comprises the step of epitaxially growing a layer doped with another doping type opposite to the one doping type.

56. The process of claim 55 further comprising the step of patterning the first monocrystalline layer, second monocrystalline layer, and third monocrystalline layer to form a p-i-n diode.

57. The process of claim 56 further comprising the step of forming electrodes electrically contacting the first monocrystalline layer and the third monocrystalline layer.

58. The process of claim 57 further comprising the steps of:
forming an integrated circuit at least partially in the substrate; and
electrically interconnecting the integrated circuit and the electrodes.

59. The process of claim 56 further comprising the steps of:
depositing a layer of material comprising an alkali earth metal titanate overlying the p-i-n diode; and
patterning the layer of material to form an optical wave guide aligned with and optically coupled to the p-i-n diode.

60. The process of claim 45 wherein each of the steps of epitaxially growing comprises epitaxially growing by a process selected from the group consisting of MBE, MOCVD, MEE, CVD, PVD, PLD, CSD and ALE.

61. The process of claim 45 further comprising the step of thermally annealing the monocrystalline oxide layer to convert the monocrystalline oxide layer to an amorphous oxide layer.

62. The process of claim 61 wherein the step of thermally annealing comprises thermally annealing after at least the step of epitaxially growing a first monocrystalline layer.

63. A process for fabricating a compound semiconductor structure comprising the steps of:
providing a monocrystalline semiconductor substrate;
depositing an oxide layer overlying the substrate;
epitaxially growing a first barrier layer comprising a monocrystalline compound semiconductor material overlying the oxide layer;
epitaxially growing a first quantum well region comprising monocrystalline ZnBeSe overlying the first barrier layer; and
epitaxially growing a second barrier layer comprising a monocrystalline compound semiconductor material overlying the first quantum well region.

64. The process of claim 63 wherein each of the steps of epitaxially growing a first barrier layer and epitaxially growing a second barrier layer comprise epitaxially growing a layer comprising ZnBeMgSe.

65. The process of claim 63 wherein each of the steps of epitaxially growing comprises epitaxially growing by a process selected from the group consisting of MBE, MOCVD, MEE, CVD, PVD, PLD, CSD and ALE.

66. The process of claim 63 wherein the step of depositing an oxide layer comprises depositing a monocrystalline alkali earth metal titanate layer.

67. The process of claim 66 further comprising the step of forming an amorphous strain relief layer underlying the oxide layer.

68. The process of claim 66 further comprising the step of forming a monocrystalline compound semiconductor buffer layer underlying the first barrier layer.

69. The process of claim 68 wherein the step of forming a monocrystalline compound semiconductor buffer layer comprises the step of forming a layer comprising a material selected from the group consisting of GaAs and ZnSe.

70. The process of claim 69 further comprising the step of forming a template layer overlying the oxide layer.

71. The process of claim 70 wherein the step of forming a template layer comprises the step of depositing 1-10 monolayers of a material selected from the group consisting of zinc and oxygen, strontium and oxygen, barium and oxygen, titanium and arsenic, strontium, oxygen and arsenic, and strontium, gallium and oxygen.

72. The process of claim 63 further comprising the steps of:
epitaxially growing additional quantum well regions overlying the second barrier layer, each of the additional quantum well regions comprising monocrystalline ZnBeSe; and
epitaxially growing an additional monocrystalline barrier layer overlying each of the additional quantum well regions, each additional monocrystalline barrier layer comprising a compound semiconductor material having a band gap greater than the band gap of ZnBeSe.

73. The process of claim 63 further comprising the step of forming electrodes electrically coupled to the first barrier layer and to the second barrier layer.

74. The process of claim 73 further comprising the steps of:
forming an integrated circuit at least partially in the substrate; and
electrically coupling the integrated circuit to the electrodes.

75. The process of claim 63 further comprising the step of patterning the first barrier layer, first quantum well region, and second barrier layer to form a laser structure.

76. The process of claim 75 further comprising the step of depositing a cladding layer overlying the laser structure.

77. The process of claim 76 wherein the step of depositing a cladding layer comprises the step of depositing an oxide layer.

78. The process of claim 75 further comprising the steps of:
depositing a layer of alkali earth metal titanate overlying the laser structure; and
patterning the layer of alkali earth metal titanate to form an optical wave guide aligned with and optically coupled to the laser structure.
